(19) United States
(12) Patent Application Publication
(10) Pub. No.: US 2024/0364295 A1
(43) Pub. Date: Oct. 31, 2024

(54) ACOUSTIC WAVE DEVICE

(71) Applicant: Murata Manufacturing Co., Ltd., Nagaokakyo-shi (JP)

(72) Inventors: Takashi YAMANE, Nagaokakyo-shi (JP); Kazunori INOUE, Nagaokakyo-shi (JP)

(21) Appl. No.: 18/771,385

(22) Filed: Jul. 12, 2024

Related U.S. Application Data
(63) Continuation of application No. PCT/JP2023/001561, filed on Jan. 19, 2023.
(60) Provisional application No. 63/302,301, filed on Jan. 24, 2022.

(51) Int. Cl. H03H 9/02

(52) U.S. Cl. CPC H03H 9/02031; H03H 9/02102; H03H 9/02228

(57) ABSTRACT

An acoustic wave device includes a support with a thickness in a first direction, a piezoelectric layer provided in the first direction of the support, first electrode fingers provided in the first direction of the piezoelectric layer and extending in a second direction orthogonal to the first direction, and second electrode fingers facing any of the first electrode fingers in a third direction orthogonal to the first and second directions and extending in the second direction. A through-hole extends through the piezoelectric layer in the first direction. The electrode fingers and the through-hole at least partially overlap an air gap in the support in plan view in the first direction. At least one of the electrode fingers is provided in the second direction of the through-hole. The electrode fingers are not provided in the third direction of the through-hole.

### CROSS REFERENCE TO RELATED APPLICATIONS

This application claims the benefit of priority to Provisional Application No. 63/302,301 filed on Jan. 24, 2022 and is a Continuation Application of PCT Application No. PCT/JP2023/001561 filed on Jan. 19, 2023. The entire contents of each application are hereby incorporated herein by reference.

### BACKGROUND OF THE INVENTION

### 1. Field of the Invention

The present disclosure relates to acoustic wave devices.

### 2. Description of the Related Art

Japanese Unexamined Patent Application Publication No. 2012-257019 describes an acoustic wave device.

### SUMMARY OF THE INVENTION

In the acoustic wave device described in Japanese Unexamined Patent Application Publication No. 2012-257019, an air gap may occur or be located between a support substrate and a piezoelectric layer. In this case, cracks may occur in the piezoelectric layer.

Example embodiments of the present invention reduce or prevent in the piezoelectric layer.

An acoustic wave device according to an example embodiment of the present invention includes a support including a support substrate with a thickness in a first direction, a piezoelectric layer provided in the first direction of the support, a plurality of first electrode fingers provided in the first direction of the piezoelectric layer and extending in a second direction orthogonal to the first direction, and a plurality of second electrode fingers facing any of the plurality of first electrode fingers in a third direction orthogonal to the first direction and the second direction and extending in the second direction, in which the piezoelectric layer includes a through-hole extending through the piezoelectric layer in the first direction, the support includes an air gap, the plurality of first electrode fingers and the plurality of second electrode fingers at least partially overlap the air gap in plan view in the first direction, the through-hole at least partially overlaps the air gap in plan view in the first direction, at least one of the plurality of first electrode fingers and the plurality of second electrode fingers is provided in the second direction of the through-hole, and the plurality of first electrode fingers and the plurality of second electrode fingers are not provided in the third direction of the through-hole.

According to example embodiments of the present disclosure, cracks in the piezoelectric layer can be reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a perspective view illustrating an acoustic wave device according to a first example embodiment of the present invention.

FIG. 1B is a plan view illustrating an electrode structure according to the first example embodiment of the present invention.

FIG. 2 is a sectional view of a portion taken along line II-II in FIG. 1A.

FIG. 3A is a schematic sectional view for explaining a Lamb wave propagating through a piezoelectric layer of a comparative example.

FIG. 3B is a schematic sectional view for explaining a bulk wave in a first-order thickness-shear mode propagating through a piezoelectric layer of the first example embodiment of the present invention.

FIG. 4 is a schematic sectional view for explaining an amplitude direction of the bulk wave in the first-order thickness-shear mode propagating through the piezoelectric layer of the first example embodiment of the present invention.

FIG. 5 is an explanatory diagram illustrating an example of resonance characteristics of the acoustic wave device according to the first example embodiment of the present invention.

FIG. 6 is an explanatory diagram illustrating the relationship between d/2p and a fractional band width of a resonator in the acoustic wave device according to the first example embodiment of the present invention, where p is a center-to-center distance or an average distance of the center-to-center distances between adjacent electrodes, and d is an average thickness of the piezoelectric layer.

FIG. 7 is a plan view illustrating an example in which a pair of electrodes are provided in the acoustic wave device according to the first example embodiment of the present invention.

FIG. 8 is a reference diagram illustrating an example of the resonance characteristics of the acoustic wave device according to the first example embodiment of the present invention.

FIG. 9 is an explanatory diagram illustrating the relationship between a fractional band width and a phase rotation amount of a spurious impedance normalized by 180 degrees as a magnitude of spurious when a large number of acoustic wave resonators are configured in the acoustic wave device according to the first example embodiment of the present invention.

FIG. 10 is an explanatory diagram illustrating a relationship among d/2p, a metallization ratio MR, and a fractional band width.

FIG. 11 is an explanatory diagram illustrating a map of the fractional band width with respect to Euler angles (0°, θ, ψ) of LiNbO₃ when d/p is infinitely close to 0.

FIG. 12 is a partially cutaway perspective view for explaining an acoustic wave device according to an example embodiment of the present invention.

FIG. 13 is a schematic plan view illustrating an example of the acoustic wave device according to the first example embodiment of the present invention.

FIG. 14 is a sectional view taken along line XIV-XIV in FIG. 13.

FIG. 15 is a sectional view taken along line XV-XV in FIG. 13.

FIG. 16 is a schematic plan view illustrating a first modification of the acoustic wave device according to the first example embodiment of the present invention.

FIG. 17 is a schematic plan view illustrating a second modification of the acoustic wave device according to the first example embodiment of the present invention.

FIG. 18 is a schematic plan view illustrating a third modification of the acoustic wave device according to the first example embodiment of the present invention.

FIG. 19 is a schematic plan view illustrating a fourth modification of the acoustic wave device according to the first example embodiment of the present invention.

FIG. 20 is a schematic plan view illustrating an example of an acoustic wave device according to a second example embodiment of the present invention.

FIG. 21 is a schematic plan view illustrating an example of an acoustic wave device according to a third example embodiment of the present invention.

FIG. 22 is a schematic plan view illustrating a first modification of the acoustic wave device according to the third example embodiment of the present invention.

FIG. 23 is a schematic plan view illustrating a second modification of the acoustic wave device according to the third example embodiment of the present invention.

FIG. 24 is a sectional view taken along line XXIV-XXIV in FIG. 23.

FIG. 25 is a sectional view taken along line XXV-XXV in FIG. 23.

### DETAILED DESCRIPTION OF THE EXAMPLE EMBODIMENTS

Hereinafter, example embodiments of the present disclosure will be described in detail with reference to the drawings. The present disclosure is not limited to the example embodiments. Each example embodiment described in the present disclosure is an example, and in modifications in which partial replacement or combination of configurations is possible between different example embodiments, or in the second and subsequent example embodiments, description of matters common to the first example embodiment will be omitted, and only different points will be described. In particular, the same advantageous effects obtained by the same configurations will not be described in each example embodiment.

### First Example Embodiment

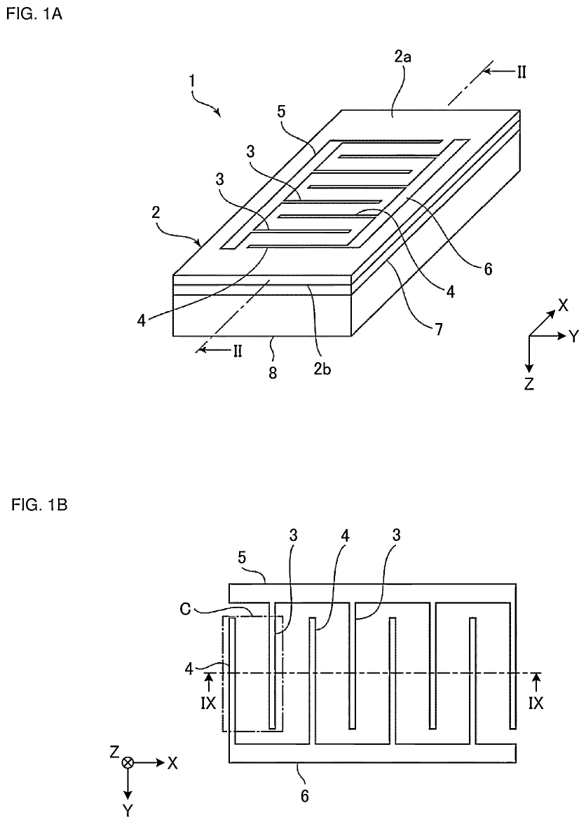

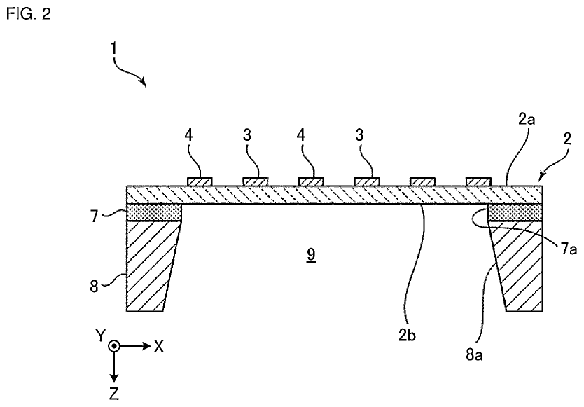

FIG. 1A is a perspective view illustrating an acoustic wave device according to a first example embodiment. FIG. 1B is a plan view illustrating an electrode structure according to the first example embodiment.

An acoustic wave device 1 of the first example embodiment includes a piezoelectric layer 2 made of LiNbO₃. The piezoelectric layer 2 may be made of LiTaO₃. The cut-angle of LiNbO₃ or LiTaO₃ is a Z-cut in the first example embodiment. The cut-angle of LiNbO₃ or LiTaO₃ may be a rotated Y-cut or X-cut. The propagation directions of Y propagation and X propagation about ±300 are preferable, for example.

The thickness of the piezoelectric layer 2 is not particularly limited, but is preferably more than or equal to about 50 nm and less than or equal to about 1000 nm in order to effectively excite the first-order thickness-shear mode.

The piezoelectric layer 2 includes a first main surface 2a and a second main surface 2b facing each other in a Z direction. Electrode fingers 3 and electrode fingers 4 are provided on the first main surface 2a.

Here, the electrode finger 3 is an example of a “first electrode finger” and the electrode finger 4 is an example of a “second electrode finger”. In FIGS. 1A and 1B, a plurality of electrode fingers 3 are a plurality of “first electrode fingers” connected to a first busbar electrode 5. A plurality of electrode fingers 4 are a plurality of “second electrode fingers” connected to a second busbar electrode 6. The plurality of electrode fingers 3 and the plurality of electrode fingers 4 are interdigitated with each other. This forms an interdigital transducer (IDT) electrode including the electrode fingers 3, the electrode fingers 4, the first busbar electrode 5, and the second busbar electrode 6.

The electrode finger 3 and the electrode finger 4 each have a rectangular or substantially rectangular shape and have a length direction. In a direction orthogonal to the length direction, the electrode finger 3 and the electrode finger 4 adjacent to the electrode finger 3 face each other. The length direction of the electrode fingers 3 and 4 and the direction orthogonal to the length direction of the electrode fingers 3 and 4 are directions intersecting a thickness direction of the piezoelectric layer 2. Therefore, it can also be said that the electrode finger 3 and the electrode finger 4 adjacent to the electrode finger 3 face each other in a direction intersecting the thickness direction of the piezoelectric layer 2. In the following description, the thickness direction of the piezoelectric layer 2 may be referred to as a Z direction (or a first direction), the length direction of the electrode finger 3 and the electrode finger 4 may be referred to as a Y direction (or a second direction), and the direction orthogonal to the length direction of the electrode finger 3 and the electrode finger 4 may be referred to as an X direction (or a third direction).

Further, the length direction of the electrode finger 3 and the electrode finger 4 may be replaced with the direction orthogonal to the length direction of the electrode finger 3 and the electrode finger 4 illustrated in FIGS. 1A and 1B. That is, the electrode finger 3 and the electrode finger 4 may extend in the direction in which the first busbar electrode 5 and the second busbar electrode 6 extend in FIGS. 1A and 1B. In this case, the first busbar electrode 5 and the second busbar electrode 6 extend in the direction in which the electrode finger 3 and the electrode finger 4 extend in FIGS. 1A and 1B. A plurality of pairs of structures in each of which the electrode finger 3 connected to one potential and the electrode finger 4 connected to the other potential are adjacent to each other are provided in the direction orthogonal to the length direction of the electrode finger 3 and the electrode finger 4 described above.

Here, the electrode finger 3 and the electrode finger 4 being adjacent to each other refers not to a case where the electrode finger 3 and the electrode finger 4 are arranged so as to be in direct contact with each other but to a case where the electrode finger 3 and the electrode finger 4 are arranged with an interval therebetween. In addition, when the electrode finger 3 and the electrode finger 4 are adjacent to each other, an electrode connected to a hot electrode or a ground electrode, including other electrode fingers 3 and 4, is not arranged between the electrode finger 3 and the electrode finger 4. The number of pairs need not be integer pairs, but may be 1.5 pairs, 2.5 pairs, or the like.

The center-to-center distance between the electrode finger 3 and the electrode finger 4, that is, the pitch is preferably in the range of more than or equal to about 1 μm and less than or equal to about 10 μm, for example. In addition, the center-to-center distance between the electrode finger 3 and the electrode finger 4 is a distance connecting the center of the width dimension of the electrode finger 3 in the direction orthogonal to the length direction of the electrode finger 3 and the center of the width dimension of the electrode finger 4 in the direction orthogonal to the length direction of the electrode finger 4.

Further, in a case where at least one of the electrode finger 3 and the electrode finger 4 includes a plurality of electrode fingers (when the electrode finger 3 and the electrode finger 4 define a pair of electrodes and there are 1.5 or more pairs of electrodes), the center-to-center distance between the electrode finger 3 and the electrode finger 4 refers to the average value of the center-to-center distances between the respective adjacent electrode fingers 3 and 4 of the 1.5 or more pairs of electrode fingers 3 and 4.

In addition, the width of the electrode fingers 3 and 4, that is, the dimension of the electrode fingers 3 and 4 in their facing direction, is preferably in the range of more than or equal to about 150 nm and less than or equal to about 1000 nm, for example. The center-to-center distance between the electrode finger 3 and the electrode finger 4 is a distance connecting the center of the dimension (width dimension) of the electrode finger 3 in the direction orthogonal to the length direction of the electrode finger 3 and the center of the dimension (width dimension) of the electrode finger 4 in the direction orthogonal to the length direction of the electrode finger 4.

In the first example embodiment, since the Z-cut piezoelectric layer is used, the direction orthogonal to the length direction of the electrode fingers 3 and 4 is a direction orthogonal to the polarization direction of the piezoelectric layer 2. This does not apply when a piezoelectric body of another cut-angle is used as the piezoelectric layer 2. Here, “orthogonal” is not limited to strictly orthogonal but may be substantially orthogonal (an angle between the direction orthogonal to the length direction of the electrode finger 3 and the electrode finger 4 and the polarization direction is, for example, about 90°±10°).

A support substrate 8 is laminated on the second main surface 2b side of the piezoelectric layer 2 with an intermediate layer 7 interposed therebetween. The intermediate layer 7 and the support substrate 8 have a frame shape and include cavities 7a and 8a as illustrated in FIG. 2. Thus, a space portion (air gap) 9 is provided.

The air gap 9 is provided so as not to interfere with the vibration of an excitation region C of the piezoelectric layer 2. Therefore, the support substrate 8 is laminated on the second main surface 2b with the intermediate layer 7 interposed therebetween at a position not overlapping a portion where at least a pair of electrode fingers 3 and 4 are provided. Note that the intermediate layer 7 need not be provided. Therefore, the support substrate 8 can be directly or indirectly laminated on the second main surface 2b of the piezoelectric layer 2.

The intermediate layer 7 may be made of silicon oxide, for example. However, the intermediate layer 7 can be made of an appropriate insulating material such as silicon oxynitride or alumina in addition to silicon oxide.

The support substrate 8 may be made of Si, for example. The plane orientation of the surface of Si on the piezoelectric layer 2 side may be (100), (110), or (111). High-resistance Si having a resistivity of more than or equal to about 4 kQ is preferable. However, the support substrate 8 can also be made using an appropriate insulating material or semiconductor material. Examples of the material of the support substrate 8 include piezoelectric bodies such as aluminum oxide, lithium tantalate, lithium niobate, or quartz crystal; various ceramics such as alumina, magnesia, sapphire, silicon nitride, aluminum nitride, silicon carbide, zirconia, cordierite, mullite, steatite, or forsterite; dielectrics such as diamond or glass; semiconductors such as gallium nitride; or the like.

The plurality of electrode fingers 3 and 4, the first busbar electrode 5, and the second busbar electrode 6 may be made of an appropriate metal or alloy such as Al or an AlCu alloy. In the first example embodiment, the electrode fingers 3 and 4, the first busbar electrode 5, and the second busbar electrode 6 have a structure in which an Al film is laminated on a Ti film. An adhesion layer other than the Ti film may be used.

At the time of driving, an AC voltage is applied between the plurality of electrode fingers 3 and the plurality of electrode fingers 4. More specifically, an AC voltage is applied between the first busbar electrode 5 and the second busbar electrode 6. As a result, it is possible to obtain resonance characteristics using a bulk wave in the first-order thickness-shear mode excited in the piezoelectric layer 2.

In the acoustic wave device 1, d/p is less than or equal to about 0.5, for example, where d is the thickness of the piezoelectric layer 2, and p is the center-to-center distance between any adjacent electrode fingers 3 and 4 of the plurality of pairs of electrode fingers 3 and 4. Therefore, the bulk wave in the first-order thickness-shear mode is effectively excited, and good resonance characteristics can be obtained. More preferably, d/p is less than or equal to about 0.24, in which case even better resonance characteristics can be obtained.

In a case where at least one of the electrode finger 3 and the electrode finger 4 includes a plurality of electrode fingers as in the first example embodiment, that is, in a case where the electrode finger 3 and the electrode finger 4 define a pair of electrodes and there are 1.5 or more pairs of the electrode finger 3 and the electrode finger 4, the center-to-center distance between the adjacent electrode fingers 3 and 4 is an average distance of the center-to-center distances between the respective adjacent electrode fingers 3 and 4.

Since the acoustic wave device 1 according to the first example embodiment has the configuration described above, even when the number of pairs of the electrode finger 3 and the electrode finger 4 is reduced in an attempt to achieve a reduction in size, Q value is less likely to be reduced. This is because the resonator does not require reflectors on both sides and has a small propagation loss. In addition, the reason why the above reflector is not required is that the bulk wave in the first-order thickness-shear mode is used.

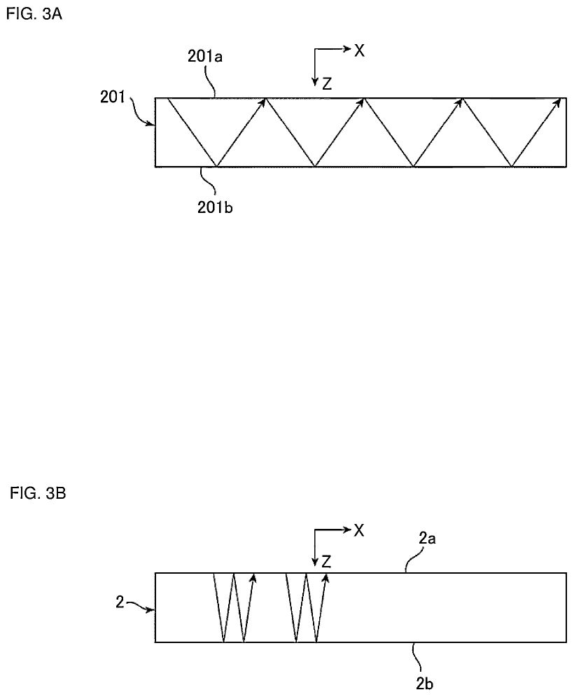

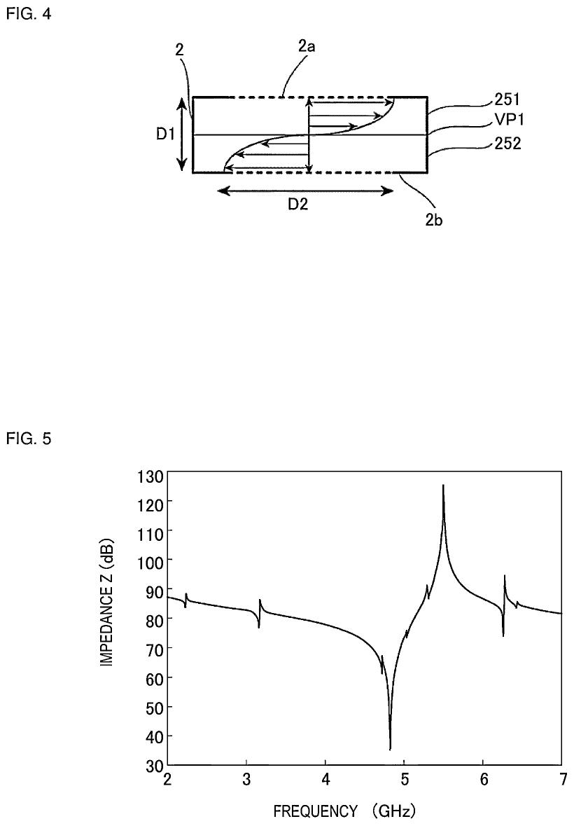

FIG. 3A is a schematic sectional view for explaining a Lamb wave propagating through a piezoelectric layer of a comparative example. FIG. 3B is a schematic sectional view for explaining a bulk wave in the first-order thickness-shear mode propagating through a piezoelectric layer of the first example embodiment. FIG. 4 is a schematic sectional view for explaining an amplitude direction of the bulk wave in the first-order thickness-shear mode propagating through the piezoelectric layer of the first example embodiment.

In FIG. 3A, an acoustic wave device as described in Patent Document 1 is illustrated, and a Lamb wave propagates through a piezoelectric layer. As illustrated in FIG. 3A, a wave propagates through a piezoelectric layer 201 as indicated by arrows. Here, the piezoelectric layer 201 includes a first main surface 201a and a second main surface 201b, and the thickness direction connecting the first main surface 201a and the second main surface 201b is the Z direction. The X direction is a direction in which electrode fingers 3 and 4 of an IDT electrode are arranged. As illustrated in FIG. 3A, the Lamb wave propagates in the X direction. Although the piezoelectric layer 201 vibrates as a whole because of the plate wave, since the wave propagates in the X direction, reflectors are arranged on both sides to obtain resonance characteristics. Therefore, a propagation loss of waves occurs, and the Q value decreases when the size is reduced, that is, when the number of pairs of electrode fingers 3 and 4 is reduced.

On the other hand, as illustrated in FIG. 3B, in the acoustic wave device of the first example embodiment, since the vibration displacement is in the thickness-shear direction, the wave substantially propagates in the direction connecting the first main surface 2a and the second main surface 2b of the piezoelectric layer 2, that is, the Z direction, and resonates. Specifically, the X direction component of the wave is significantly smaller than the Z direction component. Since resonance characteristics are obtained by the propagation of the wave in the Z direction, a reflector is not required. Therefore, propagation loss when the wave propagates to the reflector does not occur. Therefore, even when the number of pairs of electrodes including the electrode finger 3 and the electrode finger 4 is reduced in an attempt to reduce the size, the Q value is less likely to be reduced.

As illustrated in FIG. 4, the amplitude direction of the bulk wave in the first-order thickness-shear mode in a first region 251 included in the excitation region C (see FIG. 1B) of the piezoelectric layer 2 is opposite the amplitude direction thereof in a second region 252 included in the excitation region C. FIG. 4 schematically illustrates a bulk wave when a voltage is applied between the electrode finger 3 and the electrode finger 4 so that the electrode finger 4 has a higher potential than the electrode finger 3. The first region 251 is a region between the first main surface 2a and a virtual plane VP1 that is orthogonal to the thickness direction of the piezoelectric layer 2 and divides the piezoelectric layer 2 into two parts in the excitation region C. The second region 252 is a region between the virtual plane VP1 and the second main surface 2b in the excitation region C.

In the acoustic wave device 1, at least a pair of electrodes including the electrode finger 3 and the electrode finger 4 are arranged. Since waves are not propagated in the X direction, the plurality of pairs of electrodes including the electrode finger 3 and the electrode finger 4 are not always necessary. That is, only at least a pair of electrodes may be provided.

For example, the electrode finger 3 is an electrode connected to the hot potential and the electrode finger 4 is an electrode connected to the ground potential. However, the electrode finger 3 may be connected to the ground potential and the electrode finger 4 may be connected to the hot potential. In the first example embodiment, as described above, at least a pair of electrodes are the electrode connected to the hot potential or the electrode connected to the ground potential, and a floating electrode is not provided.

FIG. 5 is an explanatory diagram illustrating an example of resonance characteristics of the acoustic wave device according to the first example embodiment. The example design parameters of the acoustic wave device 1 having the resonance characteristics illustrated in FIG. 5 are as follows.
Piezoelectric layer 2: LiNbO₃ with Euler angles (0°, 0°, 90°)
Thickness of piezoelectric layer 2: 400 nm Length of excitation region C (see FIG. 1B): 40 μm
Number of pairs of electrodes including electrode finger 3 and electrode finger 4: 21 pairs
Center-to-center distance (pitch) between electrode finger 3 and electrode finger 4: 3 μm
Width of electrode fingers 3 and 4: 500 nm
d/p: 0.133
Intermediate layer 7: silicon oxide film with thickness of 1 μm
Support substrate 8: Si

The excitation region C (see FIG. 1B) is a region in which the electrode finger 3 and the electrode finger 4 overlap as seen in the X direction orthogonal to the length direction of the electrode fingers 3 and 4. The length of the excitation region C is a dimension of the excitation region C in the length direction of the electrode fingers 3 and 4. Here, the excitation region C is an example of an “intersection region”.

In the first example embodiment, the center-to-center distances of the electrode pairs including the electrode fingers 3 and the electrode fingers 4 are all equal in the plurality of pairs. That is, the electrode fingers 3 and the electrode fingers 4 are arranged with equal pitches.

As is clear from FIG. 5, good resonance characteristics with the fractional band width of about 12.5%, for example, are obtained even though no reflector is provided.

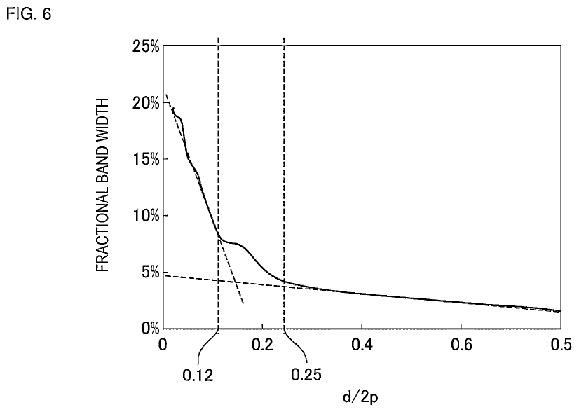

In the first example embodiment, d/p is less than or equal to about 0.5, more preferably less than or equal to about 0.24, where d is the thickness of the piezoelectric layer 2 and p is the center-to-center distance between the electrode finger 3 and the electrode finger 4. This will be described with reference to FIG. 6.

A plurality of acoustic wave devices are obtained in the same manner as the acoustic wave device having the resonance characteristics illustrated in FIG. 5, except that d/2p is changed. FIG. 6 is an explanatory diagram illustrating the relationship between d/2p and a fractional band width of a resonator in the acoustic wave device of the first example embodiment, where p is the center-to-center distance or the average distance of the center-to-center distances between adjacent electrodes, and d is the average thickness of the piezoelectric layer 2.

As illustrated in FIG. 6, when d/2p exceeds about 0.25, that is, d/p> about 0.5, the fractional band width is less than about 5% even when d/p is adjusted, for example. On the other hand, when d/2p≤ about 0.25, that is, d/p≤ about 0.5, the fractional band width can be more than or equal to about 5% by changing d/p within the range, for example, that is, the resonator having a high coupling coefficient can be provided. In addition, when d/2p is less than or equal to about 0.12, that is, d/p is less than or equal to about 0.24, the fractional band width can be increased to more than or equal to about 7%, for example. In addition, when d/p is adjusted within this range, a resonator having a wider fractional band width can be obtained, and a resonator having a higher coupling coefficient can be realized. Therefore, it is understood that by setting d/p to less than or equal to about 0.5, for example, a resonator having a high coupling coefficient using the bulk wave in the first-order thickness-shear mode described above can be provided.

Note that the at least one pair of electrodes may be a pair of electrodes, and in the case of one pair of electrodes, p is the center-to-center distance between the adjacent electrode fingers 3 and 4. Further, in the case of 1.5 or more pairs of electrodes, p may be the average distance of the center-to-center distances between the adjacent electrode fingers 3 and 4.

For the piezoelectric layer 2, when the piezoelectric layer 2 has variations in thickness d, a value obtained by averaging the thicknesses may be used.

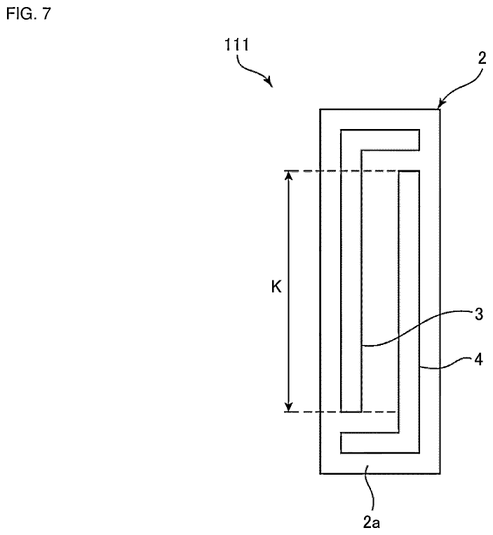

FIG. 7 is a plan view illustrating an example in which a pair of electrodes are provided in the acoustic wave device of the first example embodiment. In an acoustic wave device 111, a pair of electrodes including the electrode finger 3 and the electrode finger 4 are provided on the first main surface 2a of the piezoelectric layer 2. K in FIG. 7 is an intersecting width. As described above, in the acoustic wave device of the present disclosure, the number of pairs of electrodes may be one. Also in this case, when d/p is less than or equal to about 0.5, for example, the bulk wave in the first-order thickness-shear mode can be effectively excited.

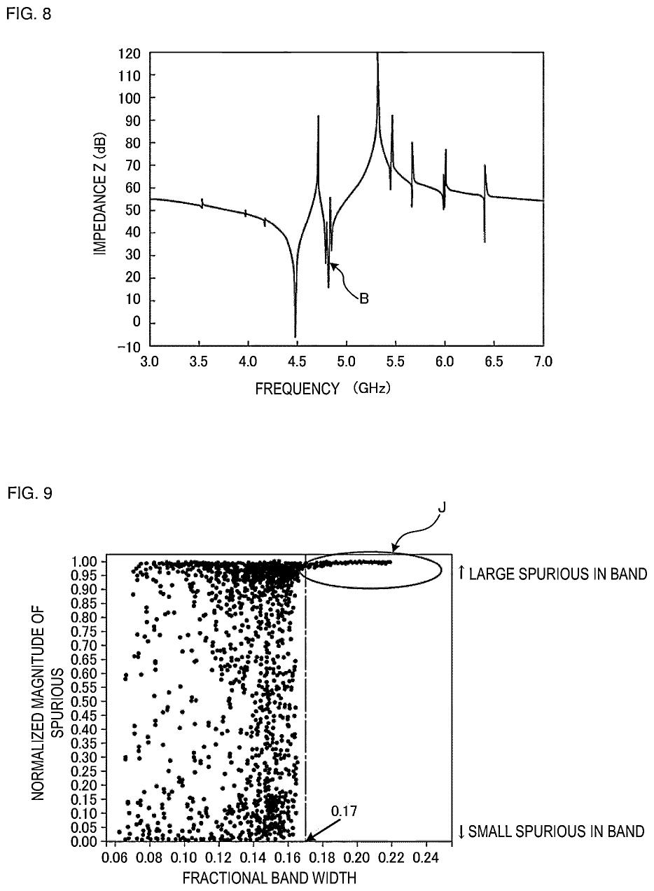

In the acoustic wave device 1, it is preferable that the metallization ratio MR of any adjacent electrode finger 3 and electrode finger 4 of the plurality of electrode fingers 3 and electrode fingers 4 with respect to the excitation region C, which is a region where the adjacent electrode finger 3 and electrode finger 4 overlap when viewed in the direction in which they face each other, satisfies MR about 1.75(d/p)+0.075, for example. In that case, it is possible to effectively reduce spurious. This will be described with reference to FIGS. 8 and 9.

FIG. 8 is a reference diagram illustrating an example of the resonance characteristics of the acoustic wave device according to the first example embodiment. A spurious indicated by an arrow B appears between a resonant frequency and an anti-resonant frequency. Note that d/p=about 0.08 and the Euler angles of LiNbO₃ are (0°, 0°, 90°), for example. The metallization ratio MR is about 0.35, for example.

The metallization ratio MR will be described with reference to FIG. 1B. In the electrode structure of FIG. 1B, when a pair of electrode fingers 3 and 4 are focused on, it is assumed that only the pair of electrode fingers 3 and 4 are provided. In this case, a portion surrounded by a dashed-dotted line is the excitation region C. When the electrode finger 3 and the electrode finger 4 are viewed in the direction orthogonal to the length direction of the electrode finger 3 and the electrode finger 4, that is, viewed in their facing direction, the excitation region C is a region of the electrode finger 3 that overlaps the electrode finger 4, a region of the electrode finger 4 that overlaps the electrode finger 3, and a region between the electrode finger 3 and the electrode finger 4 where the electrode finger 3 and the electrode finger 4 overlap each other. An area of the electrode fingers 3 and 4 in the excitation region C with respect to the area of the excitation region C is the metallization ratio MR. That is, the metallization ratio MR is the ratio of the area of the metallization portion to the area of the excitation region C.

When a plurality of pairs of electrode fingers 3 and 4 are provided, the ratio of the metallization portion included in the entire excitation region C to the total area of the excitation region C may be MR.

FIG. 9 is an explanatory diagram illustrating a relationship between a fractional band width and a phase rotation amount of the spurious impedance normalized by 180 degrees as the magnitude of the spurious when a large number of acoustic wave resonators are configured in the acoustic wave device according to the first example embodiment. The fractional band width is adjusted by changing the film thickness of the piezoelectric layer 2 and the dimensions of the electrode fingers 3 and 4. FIG. 9 illustrates the results when a Z-cut LiNbO₃ piezoelectric layer 2 is used, but the same tendency is obtained also when piezoelectric layers 2 with other cut-angles are used.

In a region surrounded by an ellipse J in FIG. 9, the spurious is as large as about 1.0, for example. As is clear from FIG. 9, when the fractional band width exceeds about 0.17, that is, exceeds about 17%, for example, a large spurious with a spurious level of more than or equal to 1 appears in a pass band even when the parameters defining the fractional band width are changed. That is, as in the resonance characteristics illustrated in FIG. 8, a large spurious indicated by the arrow B appears within the band. Therefore, the fractional band width is preferably less than or equal to about 17%, for example. In this case, the spurious can be reduced by adjusting the film thickness of the piezoelectric layer 2, the dimensions of the electrode fingers 3 and 4, or the like.

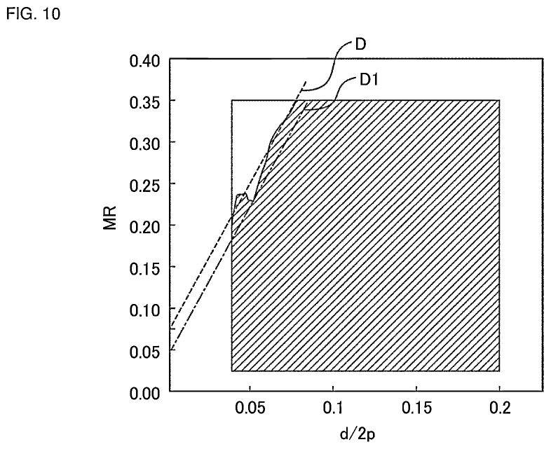

FIG. 10 is an explanatory diagram illustrating a relationship among d/2p, the metallization ratio MR, and the fractional band width. In the acoustic wave device 1 according to the first example embodiment, various acoustic wave devices 1 having different values of d/2p and different values of MR are provided, and the fractional band width is measured. A hatched portion to the right of a dashed line D illustrated in FIG. 10 is a region where the fractional band width is less than or equal to about 17%, for example. The boundary between the hatched region and the non-hatched region is represented by MR=about 3.5(d/2p)+0.075, for example. That is, MR=about 1.75(d/p)+0.075, for example. Therefore, MR≤ about 1.75(d/p)+0.075 is preferably satisfied. In this case, the fractional band width is more likely to be less than or equal to about 17%, for example. It is more preferable to be the region in FIG. 10 to the right of a dashed-dotted line D1 indicating MR=about 3.5(d/2p)+0.05, for example. That is, when MR about 1.75(d/p)+0.05, the fractional band width can be reliably set to less than or equal to about 17%, for example.

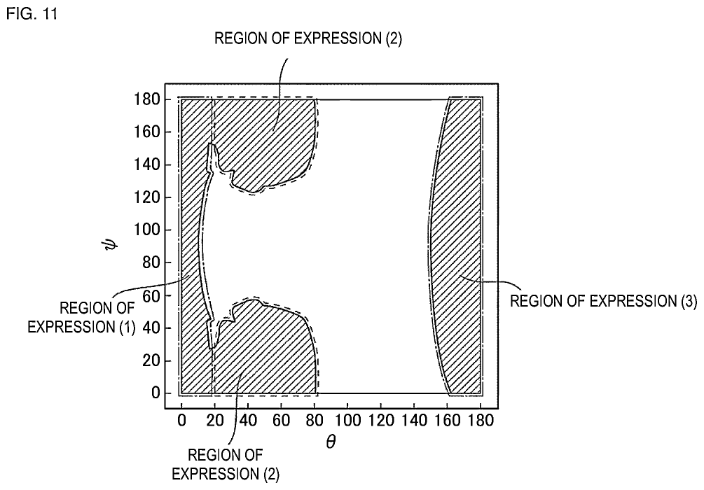

FIG. 11 is a diagram illustrating a map of the fractional band width with respect to the Euler angles (0°, θ, ψ) of LiNbO₃ when d/p is infinitely close to 0. A hatched portion in FIG. 11 is a region where the fractional band width of at least more than or equal to 5% is obtained, and the range of the region is approximated by Expressions (1), (2), and (3) below.

$$( 0 ° \pm 10 ° , 0 ° to 20 ° , any ψ ) \qquad Expression ( 1 )$$

$$0 ° \pm 10 ° , 20 ° to 80 ° , 0 ° to 60 ° {( 1 - {( θ - 50 )}^{2} / 900 )}^{1 / 2} ) or \\ ( 0 ° \pm 10 ° , 20 ° to 80 ° , [ 180 ° - 60 ° {( 1 - {( θ - 50 )}^{2} / 900 )}^{1 / 2} ] to 180 ° \qquad Expression ( 2 )$$

$$( 0 ° \pm 10 ° , [ 180 ° - 30 ° {( 1 - {( ψ - 90 )}^{2} / 8100 )}^{1 / 2} ] to 180 ° , any ψ ) \qquad Expression ( 3 )$$

Therefore, in the case of the Euler angle range of Expression (1), Expression (2), or Expression (3), the fractional band width can be sufficiently widened, which is preferable.

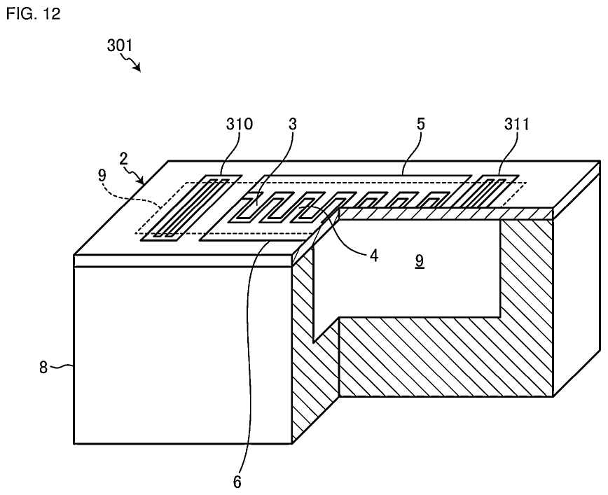

FIG. 12 is a partially cutaway perspective view for explaining an acoustic wave device according to an example embodiment of the present disclosure. In FIG. 12, an outer periphery of the air gap 9 is indicated by a dashed line. The acoustic wave device of the present disclosure may use plate waves. In this case, as illustrated in FIG. 12, an acoustic wave device 301 has reflectors 310 and 311. The reflectors 310 and 311 are provided on both sides of the electrode fingers 3 and 4 of the piezoelectric layer 2 in the acoustic wave propagation direction. In the acoustic wave device 301, a Lamb wave as a plate wave is excited by applying an AC electric field to the electrode fingers 3 and 4 above the air gap 9. Since the reflectors 310 and 311 are provided on both sides, resonance characteristics due to the Lamb wave as a plate wave can be obtained.

As described above, in the acoustic wave devices 1, a first-order thickness shear mode bulk wave is used. Further, in the acoustic wave devices 1 and 101, the first electrode finger 3 and the second electrode finger 4 are adjacent electrodes, and d/p is less than or equal to about 0.5, for example, where d is the thickness of the piezoelectric layer 2 and p is the center-to-center distance between the first electrode finger 3 and the second electrode finger 4. As a result, the Q value can be increased even when the size of the acoustic wave device is reduced.

In the acoustic wave devices 1, the piezoelectric layer 2 is made of lithium niobate or lithium tantalate. The first main surface 2a or the second main surface 2b of the piezoelectric layer 2 has the first electrode finger 3 and the second electrode finger 4 facing each other in a direction intersecting the thickness direction of the piezoelectric layer 2, and the first electrode finger 3 and the second electrode finger 4 are preferably covered with a protective film.

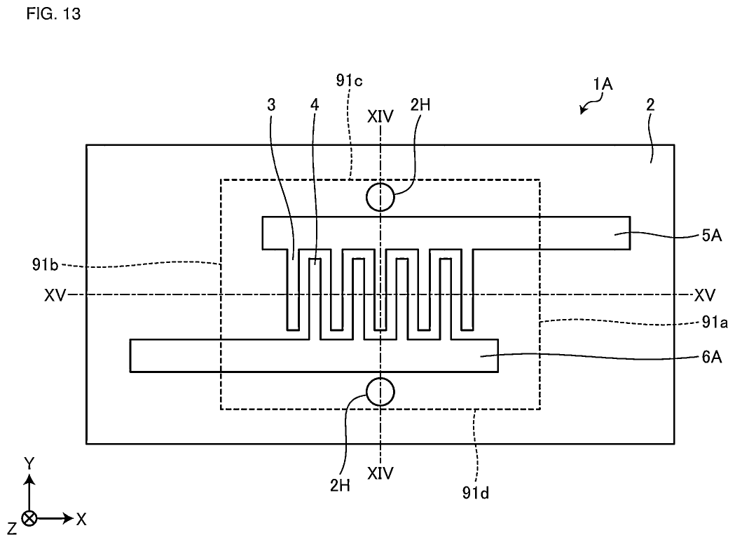

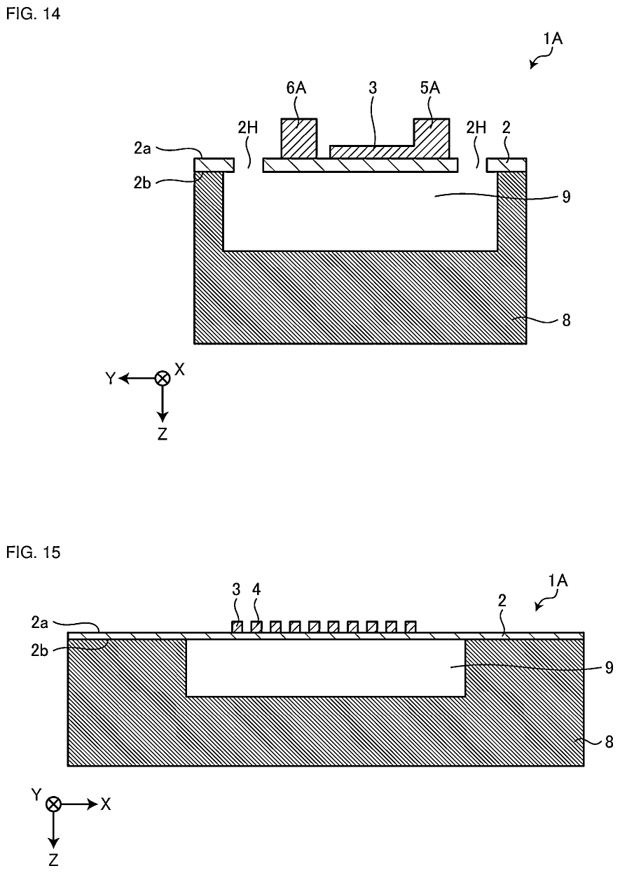

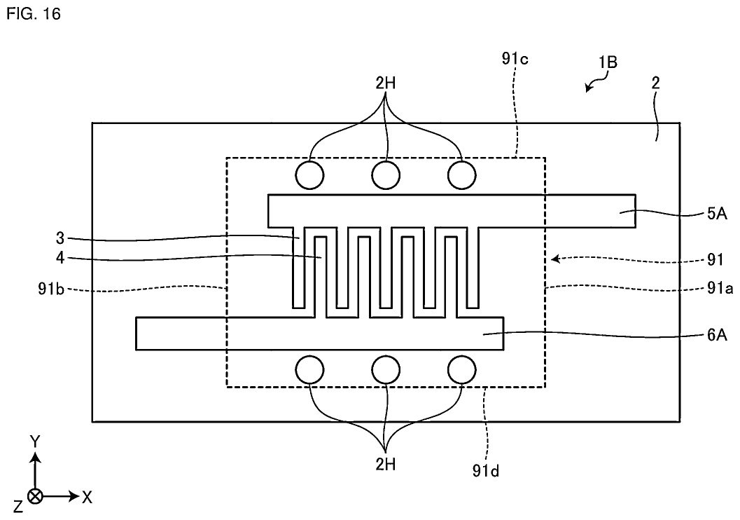

FIG. 13 is a schematic plan view illustrating an example of an acoustic wave device according to the first example embodiment. FIG. 14 is a sectional view taken along line XIV-XIV in FIG. 13. FIG. 15 is a sectional view taken along line XV-XV in FIG. 13. As illustrated in FIGS. 13 to 15, an acoustic wave device 1A according to the first example embodiment includes a support, a piezoelectric layer 2, and a functional electrode.

The support includes a support substrate 8. In the example of FIG. 13, the support is a support substrate 8. The support includes an air gap 9. In the example of FIG. 13, the air gap 9 is a rectangular parallelepiped space on the piezoelectric layer 2 side of the support substrate 8, but is not limited thereto and may pass through the support substrate 8 in the Z direction.

The functional electrode is an IDT electrode including a plurality of first electrode fingers 3, a plurality of second electrode fingers 4, a first busbar electrode 5, and a second busbar electrode 6. In the first example embodiment, the functional electrode is provided on the first main surface 2a of the piezoelectric layer 2 so as to at least partially overlap the air gap 9 when viewed in plan view in the Z direction.

The plurality of first electrode fingers 3 and the plurality of second electrode fingers 4 are provided on the first main surface 2a of the piezoelectric layer 2 so as to at least partially overlap the air gap 9 when viewed in plan view in the Z direction. In the first example embodiment, the plurality of first electrode fingers 3 and the plurality of second electrode fingers 4 overlap the air gap 9 when viewed in plan view in the Z direction.

At least one of the first busbar electrode 5A and the second busbar electrode 6A is provided on the first main surface 2a of the piezoelectric layer 2 so as to overlap at least a portion of the boundary 91 in plan view in the Z direction. Here, the boundary 91 refers to the boundary between a region of the piezoelectric layer 2 that overlaps the air gap 9 and a region of the piezoelectric layer 2 that does not overlap the air gap 9 in plan view in the Z direction. In other words, the boundary 91 can be said to be the boundary of the region, in which the air gap 9 extends, that overlaps the piezoelectric layer 2 in plan view in the Z direction. In the example of FIG. 13, the boundary 91 is a rectangle having two sides 91a and 91b parallel to the Y direction and two sides 91c and 91d parallel to the X direction. In the example of FIG. 13, the first busbar electrode 5A overlaps a portion of one side (side 91a) of the boundary 91 that is parallel to the Y direction, and the second busbar electrode 6A overlaps a portion of the other side (side 91b) of the boundary 91 that is parallel to the Y direction. As a result, the region of the piezoelectric layer 2 that overlaps the air gap 9 and the region of the piezoelectric layer 2 that does not overlap the air gap 9 in plan view in the Z direction are supported by the busbar electrodes 5A and 6A. This makes it possible to reduce or prevent occurring in the piezoelectric layer 2.

The piezoelectric layer 2 is provided in the Z direction of the support. In the first example embodiment, the piezoelectric layer 2 is provided in the Z direction of the support substrate 8. The piezoelectric layer 2 is provided with a through-hole 2H.

The through-hole 2H is a hole that passes through the piezoelectric layer 2 in the Z direction. In the first example embodiment, the through-hole 2H is communicated with the air gap 9. In this case, in the manufacturing of the acoustic wave device 1A, the through-hole 2H can be used as an injection hole (etching hole) for an etching solution in the process of etching a sacrificial layer provided in the air gap 9. Note that the shape of the through-hole 2H is circular or substantially circular in plan view in the Z direction, which is merely an example, and is not limited thereto.

The through-hole 2H is provided so as to at least partially overlap the air gap 9 in plan view in the Z direction. In the first example embodiment, at least one of the plurality of electrode fingers 3 and 4 is provided in the Y direction of the through-hole 2H, and no electrode fingers 3 and 4 are provided in the X direction of the through-hole 2H. In the first example embodiment, the electrode fingers 3 and 4 are provided between through-holes 2H in the Y direction in plan view in the Z direction. As a result, the Y direction side of the region where the electrode fingers 3 and 4 are provided, which is a region where the piezoelectric layer 2 and the air gap 9 overlap in plan view in the Z direction, is not fixed to the support substrate 8. This makes it possible to alleviate the stress in the region and to reduce or prevent in the piezoelectric layer 2 originating from the through-holes 2H.

Note that when the acoustic wave device includes a plurality of functional electrodes and has an electrode finger that overlaps an air gap different from the air gap 9 communicated with the through-hole 2H in plan view in the Z direction, the electrode finger may be provided in the X direction of the through-hole 2H. That is, the electrode fingers 3 and 4 that overlap the same air gap 9 as the air gap 9 communicated with the through-hole 2H in plan view in the Z direction are preferably not provided in the X direction of the through-hole 2H.

The acoustic wave device according to the first example embodiment is not limited to the acoustic wave device 1A illustrated in FIGS. 13 to 15, and may be a modification described below. Note that the same components as those illustrated in FIG. 13 are denoted by the same reference numerals and description thereof will be omitted.

FIG. 16 is a schematic plan view illustrating a first modification of the acoustic wave device according to the first example embodiment. As illustrated in FIG. 16, an acoustic wave device 1B according to the first modification has a plurality of through-holes 2H on the same side in the Y direction with respect to the electrode fingers 3 and 4. Note that in the example of FIG. 16, three through-holes 2H are provided on each side of the electrode fingers 3 and 4 in the Y direction, but this is merely an example. The number of the through-holes 2H is not limited thereto.

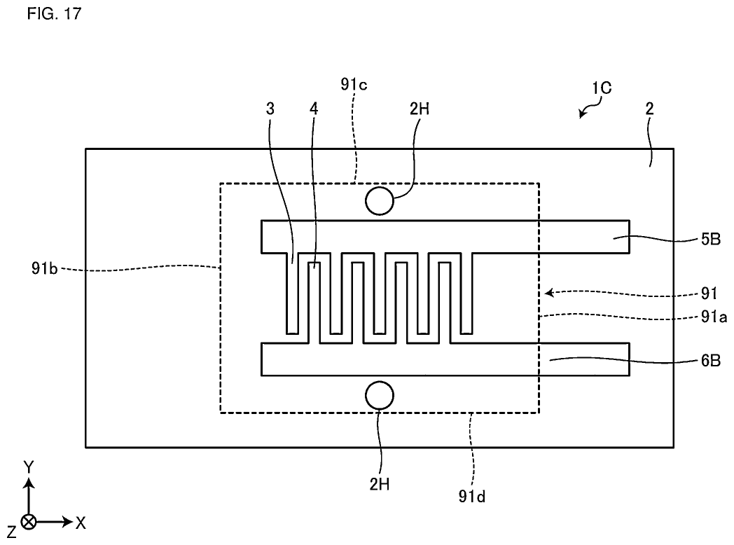

FIG. 17 is a schematic plan view illustrating a second modification of the acoustic wave device according to the first example embodiment. As illustrated in FIG. 17, in an acoustic wave device 1C according to the second modification, a first busbar electrode 5B overlaps a portion of one side (side 91a) of the boundary 91 parallel to the Y direction, and a second busbar electrode 6B overlaps a portion of one side (side 91a) of the boundary 91 parallel to the Y direction. In this case, again, the region of the piezoelectric layer 2 that overlaps the air gap 9 and the region of the piezoelectric layer 2 that does not overlap the air gap 9 in plan view in the Z direction are supported by the busbar electrodes 5B and 6B. This makes it possible to reduce or prevent occurring in the piezoelectric layer 2.

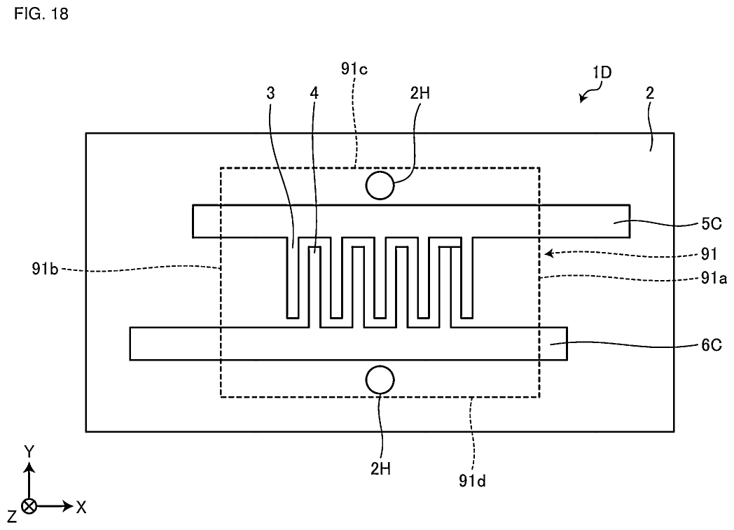

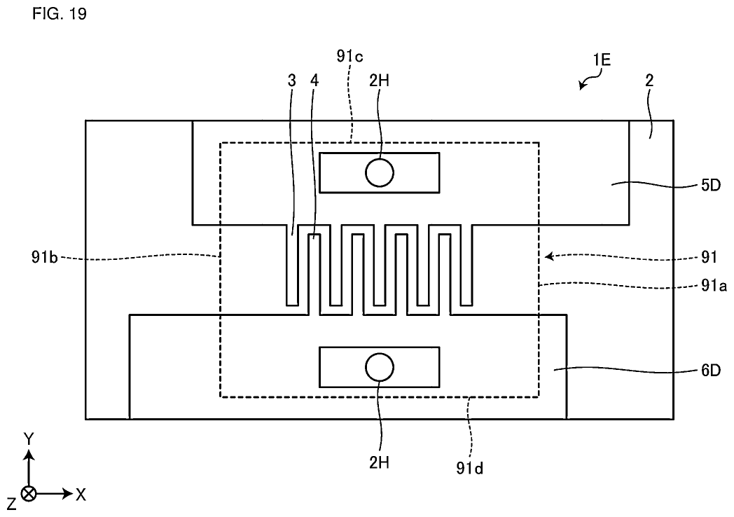

FIG. 18 is a schematic plan view illustrating a third modification of the acoustic wave device according to the first example embodiment. As illustrated in FIG. 18, in an acoustic wave device 1D according to the third modification, a first busbar electrode 5C overlaps a portion of both sides (sides 91a and 91b) of the boundary 91 parallel to the Y direction, and a second busbar electrode 6C overlaps both sides (sides 91a and 91b) of the boundary 91 parallel to the Y direction. With such a configuration, the region of the piezoelectric layer 2 that overlaps the air gap 9 and the region of the piezoelectric layer 2 that does not overlap the air gap 9 in plan view in the Z direction are more firmly supported by the busbar electrodes 5C and 6C. This makes it possible to further reduce or prevent occurring in the piezoelectric layer 2.

FIG. 19 is a schematic plan view illustrating a fourth modification of the acoustic wave device according to the first example embodiment. As illustrated in FIG. 19, in an acoustic wave device 1E according to the fourth modification, a first busbar electrode 5D overlaps both sides (sides 91a and 91b) of the boundary 91 parallel to the Y direction and one side (side 91c) parallel to the X direction, and a second busbar electrode 6D overlaps both sides (sides 91a and 91b) of the boundary 91 parallel to the Y direction and the other side (side 91d) parallel to the X direction. In the example of FIG. 19, the through-hole 2H is surrounded by the first busbar electrode 5D or the second busbar electrode 6D in plan view in the Z direction. As a result, the region of the piezoelectric layer 2 that overlaps the air gap 9 and the region of the piezoelectric layer 2 that does not overlap the air gap 9 in plan view in the Z direction are further firmly supported by the busbar electrodes 5D and 6D. This makes it possible to further reduce or prevent occurring in the piezoelectric layer 2.

As described above, the acoustic wave device according to the first example embodiment may include a support including a support substrate 8 with a thickness in a first direction (Z direction), a piezoelectric layer 2 provided in the first direction of the support, a plurality of first electrode fingers 3 provided in the first direction of the piezoelectric layer 2 and extending in a second direction (Y direction) orthogonal to the first direction, and a plurality of second electrode fingers 4 facing any of the plurality of first electrode fingers 3 in a third direction (X direction) orthogonal to the first and second directions and extending in the second direction. The piezoelectric layer 2 includes a through-hole 2H extending through the piezoelectric layer 2 in the first direction. The support includes an air gap 9. The plurality of first electrode fingers 3 and the plurality of second electrode fingers 4 at least partially overlap the air gap 9 in plan view in the first direction. The through-hole 2H at least partially overlaps the air gap 9 in plan view in the first direction. At least one of the plurality of first electrode fingers 3 and the plurality of second electrode fingers 4 is provided in the second direction of the through-hole 2H. The plurality of first electrode fingers 3 and the plurality of second electrode fingers 4 are not provided in the third direction of the through-hole 2H. As a result, in plan view in the Z direction, the Y direction side of the region where the electrode fingers 3 and 4 are provided, which is the region where the piezoelectric layer 2 and the air gap 9 overlap, is not fixed to the support substrate 8. This makes it possible to alleviate the stress on the piezoelectric layer 2 and to reduce or prevent occurring in the piezoelectric layer 2 originating from the through-hole 2H.

In an example embodiment, the through-hole 2H is communicated with the air gap 9. In this case, the through-hole 2H can be used as an etching hole in the process of etching a sacrificial layer provided in the air gap 9 in the manufacturing of the acoustic wave device 1A.

In an example embodiment, the acoustic wave device further includes a first busbar electrode 5 to which a base end of the first electrode finger 3 in the second direction is connected, and a second busbar electrode 6 provided opposite to the first busbar electrode 5 in the second direction and to which a base end of the second electrode finger 4 in the second direction is connected. At least one of the first busbar electrode 5 and the second busbar electrode 6 overlaps at least a portion of a boundary 91 between a region of the piezoelectric layer 2 that overlaps the air gap 9 and a region of the piezoelectric layer 2 that does not overlap the air gap 9 in plan view in the first direction. With such a configuration, the region of the piezoelectric layer 2 that overlaps the air gap 9 and the region of the piezoelectric layer 2 that does not overlap the air gap 9 in plan view in the Z direction are supported by the busbar electrodes 5 and 6. This makes it possible to further reduce or prevent occurring in the piezoelectric layer 2.

In an example embodiment, d/p is less than or equal to about 0.5, for example, where d is the film thickness of the piezoelectric layer 2 and p is the center-to-center distance between adjacent first electrode finger 3 and second electrode finger 4. This allows for effective excitation of a bulk wave in the first-order thickness-shear mode.

In an example embodiment, the piezoelectric layer 2 includes lithium niobate or lithium tantalate. This makes it possible to provide an acoustic wave device capable of obtaining good resonance characteristics.

In an example embodiment, the Euler angles (φ, θ, ψ) of the lithium niobate or lithium tantalate constituting the piezoelectric layer 2 are within the range of Expression (1), Expression (2), or Expression (3) below. In this case, the fractional band width can be reliably set to less than or equal to about 17%, for example.

$$( 0 ° \pm 10 ° , 0 ° to 20 ° , any ψ ) \qquad Expression ( 1 )$$

$$0 ° \pm 10 ° , 20 ° to 80 ° , 0 ° to 60 ° {( 1 - {( θ - 50 )}^{2} / 900 )}^{1 / 2} ) or \\ ( 0 ° \pm 10 ° , 20 ° to 80 ° , [ 180 ° - 60 ° {( 1 - {( θ - 50 )}^{2} / 900 )}^{1 / 2} ] to 180 ° \qquad Expression ( 2 )$$

$$( 0 ° \pm 10 ° , [ 180 ° - 30 ° {( 1 - {( ψ - 90 )}^{2} / 8100 )}^{1 / 2} ] to 180 ° , any ψ ) \qquad Expression ( 3 )$$

In an example embodiment, the acoustic wave device is structured to use bulk waves in a thickness-shear mode. This increases a coupling coefficient, making it possible to provide an acoustic wave device capable of obtaining good resonance characteristics.

In an example embodiment, d/p is less than or equal to about 0.24, for example, where d is the thickness of the piezoelectric layer 2 and p is the center-to-center distance between the adjacent first electrode finger 3 and second electrode finger 4. This makes it possible to more effectively excite the bulk wave in the first-order thickness-shear mode.

In an example embodiment, when a region where the adjacent first and second electrode fingers 3 and 4 overlap when viewed in their facing direction is an excitation region, MR≤ about 1.75(d/p)+0.075 is satisfied, for example, where MR is the metallization ratio of the plurality of first electrode fingers 3 and second electrode fingers 4 to the excitation region. This makes it possible to effectively reduce spurious.

In an example embodiment, the acoustic wave device is structured to use plate waves. This makes it possible to effectively reduce the spurious.

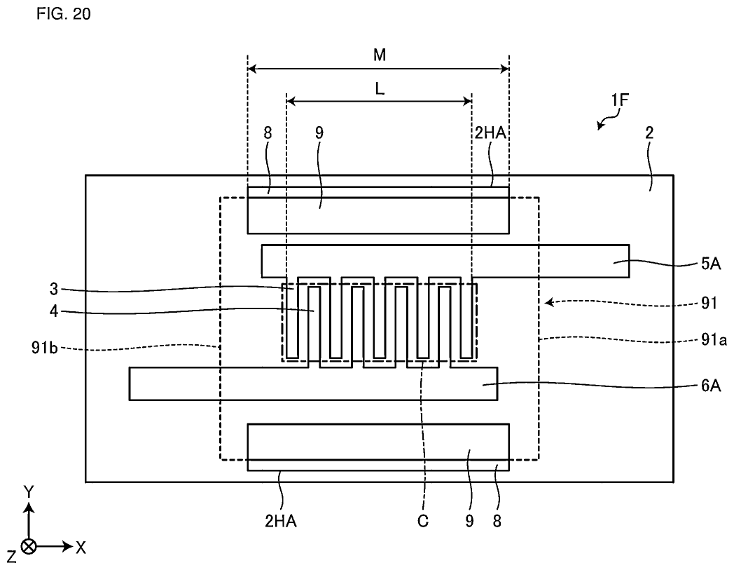

FIG. 20 is a schematic plan view illustrating an example of an acoustic wave device according to a second example embodiment. As illustrated in FIG. 20, an acoustic wave device 1F according to the second example embodiment is different from the first example embodiment in that a length M of a through-hole 2HA in the X direction is greater than a length L of an intersection region in the X direction. Here, the length M refers to the maximum length of the through-hole in the X direction, and in the example of FIG. 20, refers to the maximum length of the through-hole 2HA in the X direction. The intersection region refers to the excitation region C. That is, the length L can be said to be the dimension of the excitation region C in the direction perpendicular to the length direction of the electrode fingers 3 and 4 and perpendicular to the Z direction. In the second example embodiment, a plurality of electrode fingers 3 and 4 are located at positions overlapping the through-hole 2HA when viewed from the Y direction. That is, the through-holes 2HA are provided on both sides of all of the plurality of electrode fingers 3 and 4 in the Y direction. With such a configuration, the Y direction side of the region of the piezoelectric layer 2 that overlaps the air gap 9 and the intersection region C in plan view in the Z direction is not fixed to the support substrate 8. This makes it possible to further alleviate the stress in the region and to further reduce or prevent occurring in the piezoelectric layer 2 originating from the through-hole 2HA.

As described above, in the acoustic wave device 1F according to the second example embodiment, when the region where the first electrode fingers 3 and second electrode fingers 4 adjacent to each other overlap when viewed in the third direction is the intersection region C, the length M of the through-hole 2HA in the third direction is greater than the length L of the intersection region C in the third direction. With such a configuration, the Y-direction side of the region of the piezoelectric layer 2 that overlaps the air gap 9 and the intersection region C in plan view in the Z direction is not fixed to the support substrate 8. This makes it possible to further alleviate the stress in the region and to further reduce or prevent in the piezoelectric layer 2 originating from the through-hole 2HA.

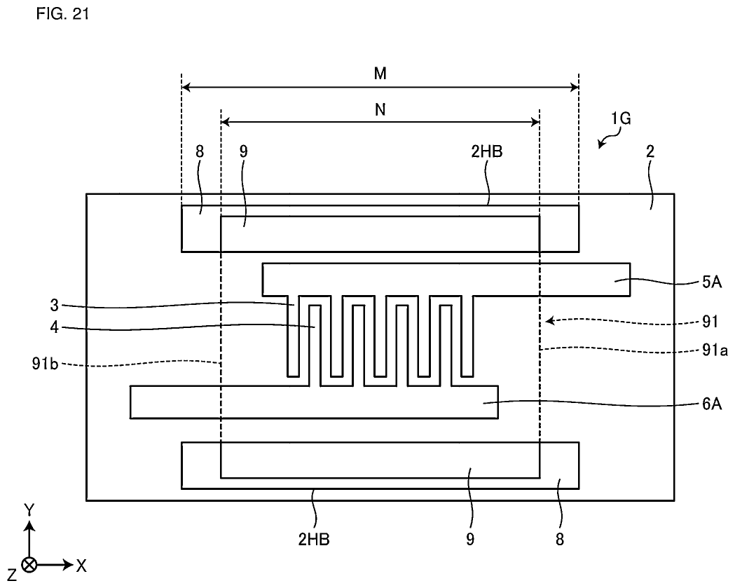

FIG. 21 is a schematic plan view illustrating an example of an acoustic wave device according to a third example embodiment. As illustrated in FIG. 21, an acoustic wave device 1G according to the third example embodiment is different from the first example embodiment in that a length M of a through-hole 2HB in the X direction is greater than a length N of a air gap 9 in the third direction. Here, in the example of FIG. 21, the length M is the maximum length of the through-hole 2HB in the X direction. Here, the length N refers to the maximum length of the air gap 9 in the X direction in plan view in the Z direction, and can be said to be the maximum distance in the X direction between boundaries 91. In the example of FIG. 21, the length N corresponds to the distance between the sides 91a and 91b of the boundary 91 parallel to each other in the Y direction. In the third example embodiment, the air gap 9 is located at a position overlapping the through-hole 2HB when viewed in the Y direction. That is, the piezoelectric layer 2 in the region overlapping the air gap 9 in plan view in the Z direction has the through-holes 2HB on both sides in the Y direction. With such a configuration, the Y-direction side of the region of the piezoelectric layer 2 that overlaps the air gap 9 in plan view in the Z direction is not fixed to the support substrate 8. This makes it possible to further alleviate the stress in the region and to further reduce or prevent in the piezoelectric layer 2 originating from the through-hole 2HB.

Note that the acoustic wave device according to the third example embodiment is not limited to the acoustic wave device 1G illustrated in FIG. 21. The acoustic wave device according to the third example embodiment may be one according to a modification described below.

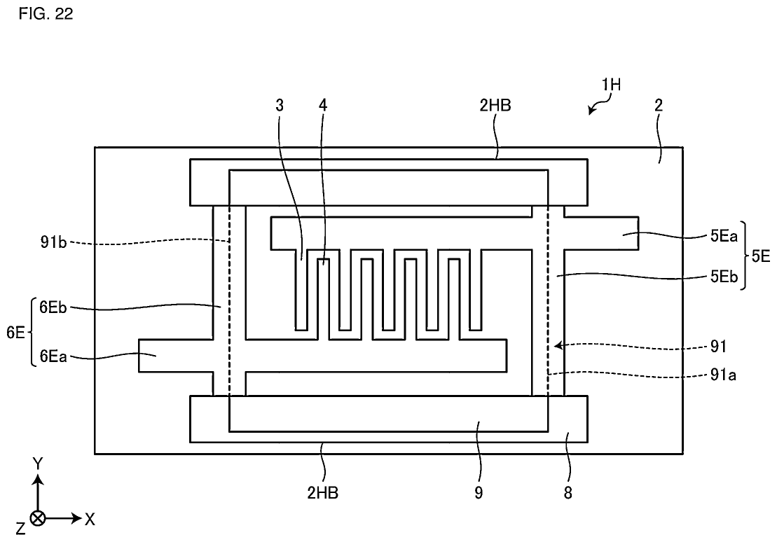

FIG. 22 is a schematic plan view illustrating a first modification of the acoustic wave device according to the third example embodiment. As illustrated in FIG. 22, in an acoustic wave device 1H according to the first modification of the third example embodiment, busbar electrodes 5E and 6E overlap the entire boundary 91. In the example of FIG. 22, the first busbar electrode 5E has a first portion 5Ea extending in the X direction and a second portion 5Eb extending in the Y direction, and the second busbar electrode 6E has a first portion 6Ea extending in the X direction and a second portion 6Eb extending in the Y direction. Here, the second portion 5Eb entirely overlaps one (side 91a) of the sides of the boundary 91 parallel to each other in the Y direction in plan view in the Z direction, and the second portion 6Eb entirely overlaps the other (side 91b) of the sides of the boundary 91 parallel to each other in the Y direction in plan view in the Z direction. With such a configuration, the region of the piezoelectric layer 2 that overlaps the air gap 9 and the region of the piezoelectric layer 2 that does not overlap the air gap 9 in plan view in the Z direction are more firmly supported by the busbar electrodes 5E and 6E. This makes it possible to further reduce or prevent in the piezoelectric layer 2.

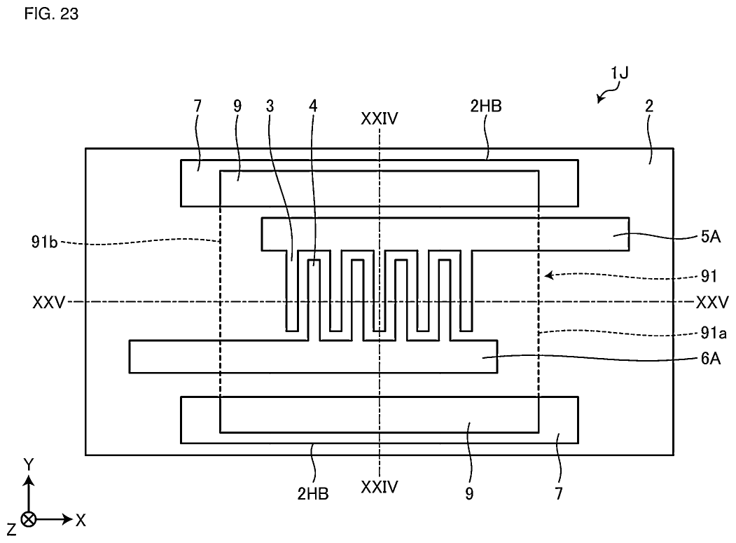

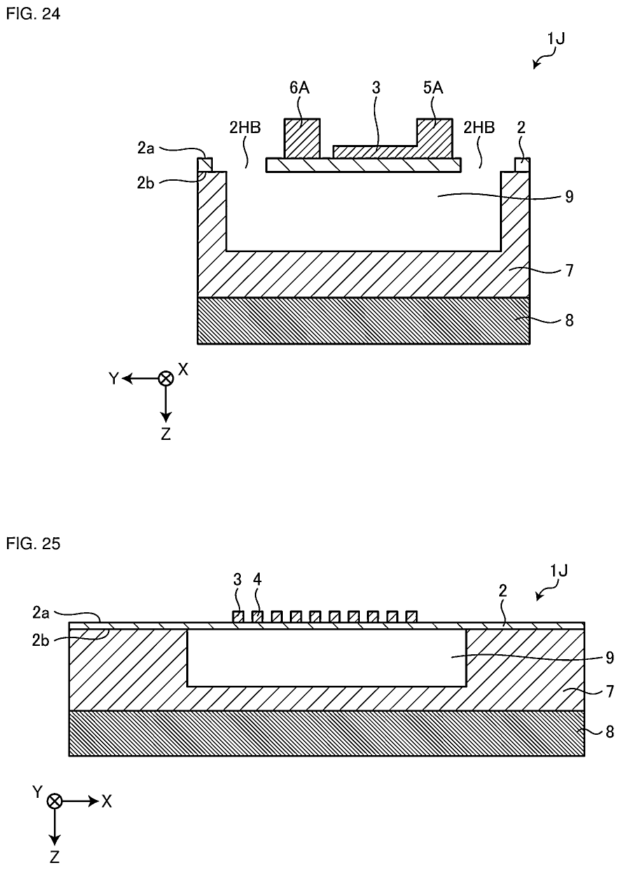

FIG. 23 is a schematic plan view illustrating a second modification of the acoustic wave device according to the third example embodiment. FIG. 24 is a sectional view taken along line XXIV-XXIV in FIG. 23. FIG. 25 is a sectional view taken along line XXV-XXV in FIG. 23. As illustrated in FIGS. 23 to 25, a support in an acoustic wave device 1J according to the second modification further includes an intermediate layer 7. The intermediate layer 7 is provided on the piezoelectric layer 2 side of a support substrate 8. In the example of FIG. 23, the intermediate layer 7 is made of silicon oxide. Note that in the example of FIGS. 24 and 25, an air gap 9 is on the piezoelectric layer 2 side of the intermediate layer 7, but is not limited thereto and may pass through the intermediate layer 7. This can improve frequency temperature characteristics of the acoustic wave device.

As described above, in the acoustic wave device 1G according to the third example embodiment, the length M of the through-hole 2H in the third direction is greater than the length N of the air gap 9 in the third direction. With such a configuration, the Y-direction side of the region of the piezoelectric layer 2 that overlaps the air gap 9 in plan view in the Z direction is not fixed to the support substrate 8. This makes it possible to further alleviate the stress in the region and to further reduce or prevent in the piezoelectric layer 2 originating from the through-hole 2HB.

The support may further include the intermediate layer 7 including silicon oxide, and the intermediate layer 7 may be provided between the support substrate 8 and the piezoelectric layer 2. This can improve the frequency temperature characteristics of the acoustic wave device.

Note that the example embodiments described above are intended to facilitate the understanding of the present disclosure and are not intended to limit the interpretation of the present disclosure. The present disclosure may be modified or improved without departing from the spirit of the present disclosure, and equivalents thereof are also included in the present disclosure.

For example, the support of the acoustic wave device according to the first and second example embodiments may further include an intermediate layer including, for example, silicon oxide. In this case, the intermediate layer is provided on the piezoelectric layer 2 side with respect to the support substrate 8. In this case, the air gap 9 may be on the piezoelectric layer 2 side of the intermediate layer, or may pass through the intermediate layer. This can improve the frequency temperature characteristics of the acoustic wave device.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a support including a support substrate with a thickness in a first direction;
a piezoelectric layer provided in the first direction of the support;
a plurality of first electrode fingers provided in the first direction of the piezoelectric layer and extending in a second direction orthogonal to the first direction; and
a plurality of second electrode fingers facing any of the plurality of first electrode fingers in a third direction orthogonal to the first direction and the second direction and extending in the second direction; wherein
the piezoelectric layer includes a through-hole extending through the piezoelectric layer in the first direction;
the support includes an air gap;
the plurality of first electrode fingers and the plurality of second electrode fingers at least partially overlap the air gap in plan view in the first direction;
the through-hole at least partially overlaps the air gap in plan view in the first direction;
at least one of the plurality of first electrode fingers and the plurality of second electrode fingers is provided in the second direction of the through-hole; and
the plurality of first electrode fingers and the plurality of second electrode fingers are not provided in the third direction of the through-hole.

2. The acoustic wave device according to claim 1, wherein the through-hole is communicated with the air gap.

3. The acoustic wave device according to claim 1, wherein, when a region where the first electrode fingers and the second electrode fingers adjacent to each other overlap when viewed in the third direction is an intersection region, a length of the through-hole in the third direction is greater than a length of the intersection region in the third direction.

4. The acoustic wave device according to claim 1, wherein a length of the through-hole in the third direction is greater than a length of the air gap in the third direction.

5. The acoustic wave device according to claim 1, further comprising:
a first busbar electrode to which a base end of each of the first electrode fingers in the second direction is connected; and
a second busbar electrode provided opposite to the first busbar electrode in the second direction and to which a base end of each of the second electrode fingers in the second direction is connected; wherein
at least one of the first busbar electrode and the second busbar electrode overlaps at least a portion of a boundary between a region of the piezoelectric layer that overlaps the air gap and a region of the piezoelectric layer that does not overlap the air gap in plan view in the first direction.

6. The acoustic wave device according to claim 1, wherein
the support further includes an intermediate layer including silicon oxide; and
the intermediate layer is provided between the support substrate and the piezoelectric layer.

7. The acoustic wave device according to claim 1, wherein d/p is less than or equal to about 0.5, where d is a film thickness of the piezoelectric layer and p is a center-to-center distance between the first electrode fingers and the second electrode fingers adjacent to each other.

8. The acoustic wave device according to claim 1, wherein the piezoelectric layer includes lithium niobate or lithium tantalate.

9. The acoustic wave device according to claim 8, wherein
Euler angles (φ, θ, ψ) of the lithium niobate or lithium tantalate included in the piezoelectric layer are within a range of Expression (1), Expression (2), or Expression (3):
$$( 0 ° \pm 10 ° , 0 ° to 20 ° , any ψ ) ; \qquad Expression ( 1 )$$
$$0 ° \pm 10 ° , 20 ° to 80 ° , 0 ° to 60 ° {( 1 - {( θ - 50 )}^{2} / 900 )}^{1 / 2} ) or \\ ( 0 ° \pm 10 ° , 20 ° to 80 ° , [ 180 ° - 60 ° {( 1 - {( θ - 50 )}^{2} / 900 )}^{1 / 2} ] to 180 ° ; or \qquad Expression ( 2 )$$
$$( 0 ° \pm 10 ° , [ 180 ° - 30 ° {( 1 - {( ψ - 90 )}^{2} / 8100 )}^{1 / 2} ] to 180 ° , any ψ ) . \qquad Expression ( 3 )$$

10. The acoustic wave device according to claim 1, wherein the acoustic wave device is structured to use a bulk wave in a thickness-shear mode.

11. The acoustic wave device according to claim 1, wherein d/p is less than or equal to about 0.24, where d is a film thickness of the piezoelectric layer and p is a center-to-center distance between the first electrode fingers and the second electrode fingers adjacent to each other.

12. The acoustic wave device according to claim 1, wherein when a region where the first electrode fingers and the second electrode fingers adjacent to each other overlap when viewed in their facing direction is an excitation region, MR≤ about 1.75(d/p)+0.075 is satisfied, where MR is a metallization ratio of the plurality of first electrode fingers and the plurality of second electrode fingers to the excitation region.

13. The acoustic wave device according to claim 1, wherein the acoustic wave device is structured to use a plate wave.

14. The acoustic wave device according to claim 1, wherein the through-hole is circular or substantially circular.

15. The acoustic wave device according to claim 1, wherein at least one of the plurality of first and second electrode fingers is provided in a Y direction of the through-hole, and none of the plurality of first and second electrode fingers is provided in a X direction of the through-hole.

16. The acoustic wave device according to claim 1, wherein the piezoelectric layer includes a plurality of the through holes.

17. The acoustic wave device according to claim 16, wherein the plurality of first and second electrode fingers are provided between the plurality of through-holes.

18. The acoustic wave device according to claim 1, wherein a portion of a region where the plurality of first and second electrode fingers are located where the air gap and the piezoelectric layer overlap is not fixed to the support substrate.

19. The acoustic wave device according to claim 5, wherein the region of the piezoelectric layer that overlaps the air gap and the region of the piezoelectric layer that does not overlap the air gap in plan view in the first direction are supported by the first and second busbar electrodes.

20. The acoustic wave device according to claim 6, wherein the air gap is on a piezoelectric layer side of the intermediate layer or extends through the intermediate layer.
